(19) United States
(12) Patent Application Publication
(10) Pub. No.: US 2011/0272780 A1
(43) Pub. Date: Nov. 10, 2011

(54) METHOD AND STRUCTURE FOR IMPROVING THE QUALILTY FACTOR OF RF INDUCTORS

(76) Inventors: Peter Smeys, San Jose, CA (US); Kyuwoon Hwang, Palo Alto, CA (US); Peter J. Hopper, San Jose, CA (US); William French, San Jose, CA (US)

(21) Appl. No.: 12/774,532

(22) Filed: May 5, 2010

(51) Int. Cl. H01L 29/86; H01L 21/02

(52) U.S. Cl. 257/531; 438/381; 257/E29.325; 257/E21.022

(57) ABSTRACT

An on-chip inductor structure is formed as part of an integrated circuit structure. The integrate circuit structure includes a semiconductor substrate having a top side and a back side, integrated circuit elements formed on the top side of the substrate, a conductive interconnect structure formed in contact with the integrated circuit elements and a passivation layer formed over the integrated circuit elements. The inductor structure comprises a layer of photoimageable epoxy formed on the passivation layer, a conductive inductor coil formed on the layer of photoimageable epoxy and at least one conductive via that extends from the inductor coil to the interconnect layer to provide electrical connection therebetween. Additionally, a back side trench may be formed in the back side of the semiconductor substrate beneath the inductor coil.

### FIELD OF THE INVENTION

The present invention relates to integrated circuit structures and, in particular, to methods and structures for increasing the quality factor Q of on-chip RF inductors by reducing eddy currents in the underlying substrate.

### BACKGROUND OF THE INVENTION

In order to increase the quality factor of an on-chip RF inductor, it is essential to minimize losses. Losses in RF inductors are dominated by capacitive effects and by eddy currents in the inductor coil and the underlying substrate.

Eddy currents are induced in a conductive medium in proximity to the inductor by the magnetic field that surrounds the inductor coil. The magnetic field decays in inverse relationship to the distance from the coil. Hence, eddy currents in the substrate can be reduced in two ways: (1) move the inductor coil farther away for the substrate and (2) eliminate the conductive medium around the coil or make the substrate more resistive.

### SUMMARY OF THE INVENTION

The present invention provides an on-chip inductor structure that is formed as part of an integrated circuit structure. The integrated circuit structure includes a semiconductor substrate having a top side and a back side, circuit elements formed on the top side of the substrate, a conductive interconnect layer formed in contact with the circuit elements, and a passivation layer formed over the integrated circuit elements. The inductor structure comprises a layer of photoimageable epoxy formed on the passivation layer, a conductive inductor coil formed on the layer of photoimageable epoxy, and at least one conductive via that extends from the inductor coil to the conductive interconnect layer to provide electrical contact therebetween. Additionally, a back side trench may be formed in the back side of the semiconductor substrate beneath the inductor coil.

The features and advantages of the various aspects of the present invention will be more fully understood and appreciated upon consideration of the following detailed description of the invention and the accompanying drawings, which set forth illustrative embodiments in which the concepts of the invention are utilized.

### BRIEF DESCRIPTION OF THE DRAWINGS

FIG. 1 is a cross section drawing schematically illustrating an embodiment of an on-chip inductor structure in accordance with the present invention.

FIG. 2 is a graph providing a comparison between the quality factor of a conventional RF inductor and an embodiment of an on-chip inductor structure in accordance with the concepts of the present invention.

FIGS. 3A-3D are cross section drawings schematically illustrating an embodiment of a sequence of steps for fabricating an on-chip inductor structure in accordance with the concepts of the present invention.

### DETAILED DESCRIPTION OF THE INVENTION

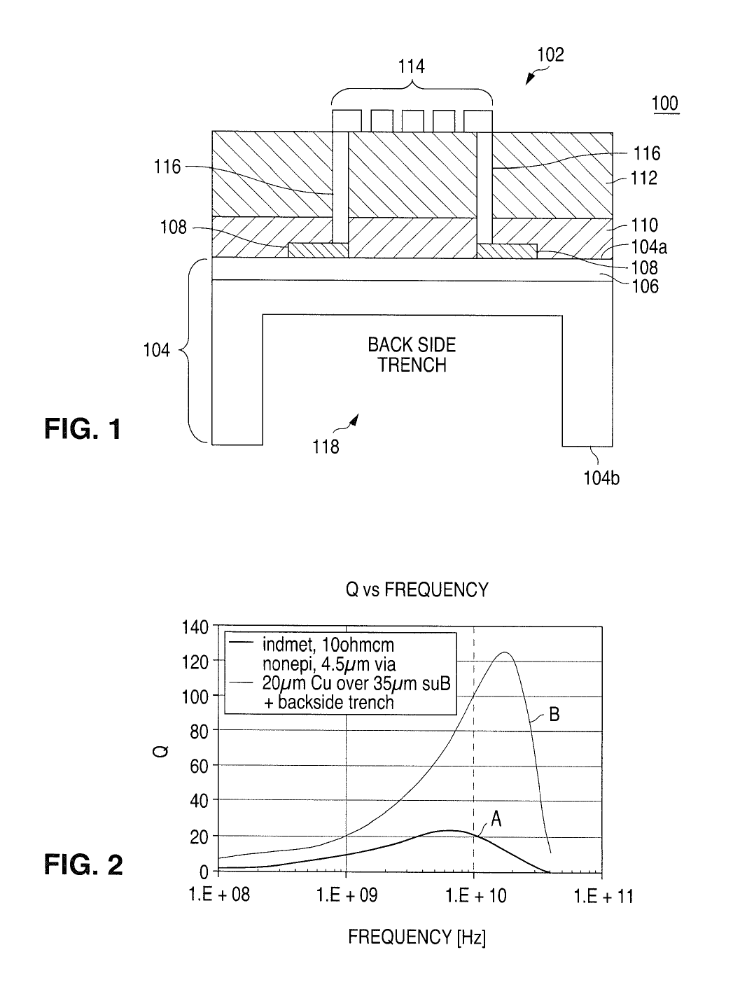

FIG. 1 shows an integrated circuit structure 100 that includes an on-chip inductor structure 102. The integrated circuit structure 100 includes a semiconductor substrate 104, typically crystalline silicon, having a top side 104a and a back side 104b. Integrated circuit elements 106 of the type that are well known to those skilled in the art are formed on the top side 104a of the semiconductor substrate 104 in the well know manner; since the integrated circuit elements 106 may be embodied in any number of circuit configurations, these elements are represented schematically in FIG. 1 as circuit layer 106. Although these elements may be discrete, they are typically interconnected to provide integrated circuitry. A conductive interconnect layer 108, typically a patterned metal layer (e.g. Cu or Al or alloys thereof), electrically connects features of the integrated circuit elements 106. For example, the interconnect layer 108 may be the top metal layer of integrated circuitry that includes

CMOS integrated circuit structures. A passivation layer 110 is formed over the integrated circuit elements 106, including over the conductive interconnect layer 108. The passivation layer 110 may be formed by plasma deposition of an oxide (e.g. SiO₂) followed by plasma deposition of a silicon nitride. Typically, the thickness of the passivation layer is about 600 nm-1 μm.

With continuing reference to the FIG. 1 embodiment, the on-chip inductor structure 102 includes a layer of photoimageable epoxy 112 formed on the passivation layer 110, a conductive inductor coil 114 that is formed on the layer of photoimageable epoxy 112, and one or more conductive vias 116 that, in the FIG. 1 embodiment, extend through the photoimageable epoxy layer 112 and the passivation layer 110 from the conductive inductor coil 114 to the conductive interconnect layer 108 to provide electrical contact therebetween. As discussed in greater detail below, the semiconductor substrate 104 may also include a back side trench 118 that is formed in the back side 104b of the substrate 104 beneath the inductor coil 114. The epoxy layer 112 may be a photoimageable spin-on epoxy such as, for example, SU-8. It is spun on the wafer, softbaked, exposed, developed and hardbaked to form the vias down to the underlying conductive interconnect layer 108 using a standard lithography tool.

The conductive inductor coil 114 may be formed by electroplating. In an embodiment, a seed layer (e.g., Ti/Cu) is sputtered onto the epoxy layer 112, covering the surface of the wafer as well as the sidewalls and bottom of the vias. Subsequently, a thick resist is spun on and exposed. The copper coil 114 is then electroplated to a desired thickness. In an embodiment, the inductor coil is a spiral.

Thus, in an embodiment of the invention, eddy currents in the on-chip inductor structure 102 are reduced by fabricating the inductor coil 114 on top of an SU-8 photoimageable epoxy layer 112 of up to 250 μm thickness, for example by spinning on the epoxy layer 112 after completion of passivation of underlying CMOS circuitry, as described above. The contact from the inductor 114 down to the active silicon is made during formation of the coil 114 by electroplating vias 116 formed through the SU-8 layer 112 and the passivation layer 110 that connect the coil 114 to the top metal interconnect layer 108.

As further shown in the FIG. 1 embodiment, eddy currents can be further reduced by removing the substrate 104 from beneath the inductor structure 102 by using back side trench etching, thereby removing the conductive medium away from the inductor structure 102, effectively increasing the resistivity of the substrate 104 beneath the inductor coil 114 to infinity.

By employing formation of the inductor coil 114 on a thick epoxy layer 112, a quality factor of approximately 60 can be obtained in an RF inductor. If the additional step of removing the underlying substrate by forming a back side trench is included in the process, a quality factor of approximately 130 can be obtained. This is in contrast to quality factors of the order of 10-25 that are typical for conventional RF inductors.

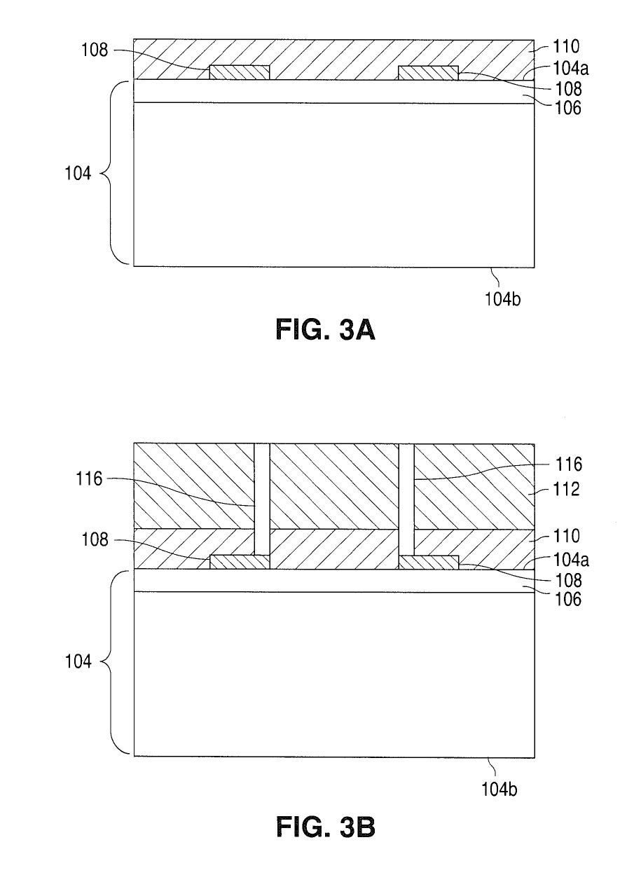

FIG. 2 shows simulation results comparing the quality factor Q of a conventional RF inductor built using standard CMOS metal (line A in FIG. 2) and an embodiment of an on-chip inductor structure of the type shown in FIG. 1(line B in FIG. 2). In the FIG. 2 example, a thickness of 35 μm of SU-8 was used together with a 20 μm Cu inductor coil layer. As shown in the FIG. 2, the FIG. 1 inductor structure achieves a quality factor greater than 120 at higher frequencies (2 GHz).

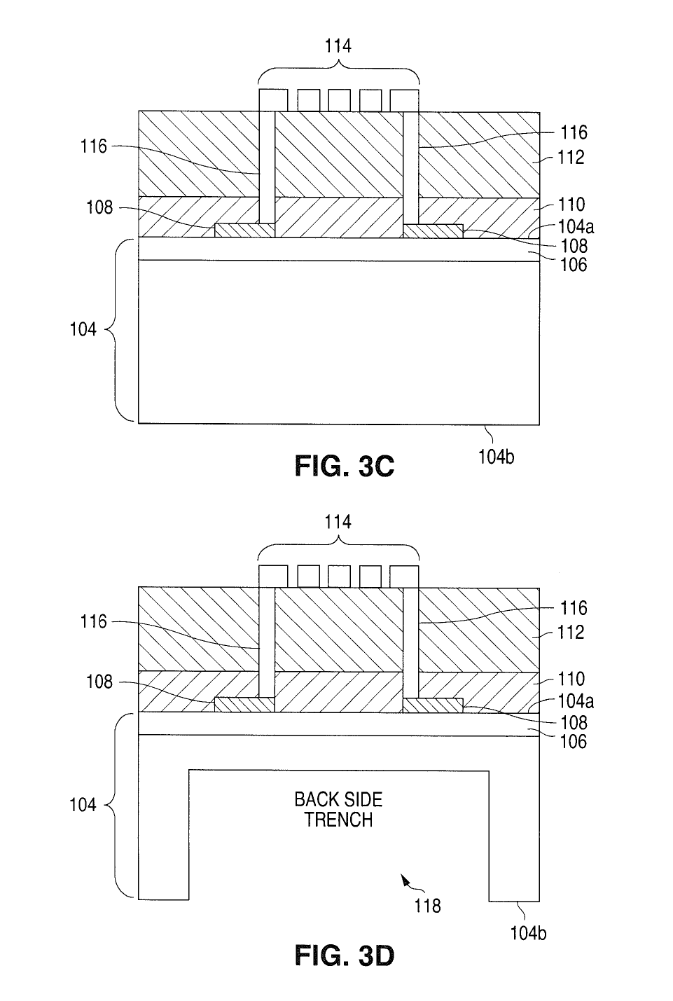

FIGS. 3A-3D schematically illustrate an embodiment of a sequence of steps for fabricating an on-chip inductor structure of the type shown in FIG. 1. The reference numerals utilized in FIG. 1 are also utilized in FIGS. 3A-3D to identify similar structural features.

FIG. 3A shows an integrated circuit structure that includes a semiconductor substrate 104, typically crystalline silicon, having a top side 104a and a back side 104b. Circuit elements 106 of the type that are well known to those skilled in the art are formed on the top side 104a of the semiconductor substrate 104 in the well known manner. Although these elements 106 may be discrete, they are typically interconnected to provide integrated circuitry. A conductive interconnect layer 108, typically a patterned metal layer (e.g., Cu or Al or alloys thereof), electrically interconnects features of the circuit elements 106. For example, the interconnect layer 108 may be the top metal layer that interconnects features of integrated circuitry that includes CMOS integrated circuit features. A passivation layer 110 is formed over the circuit elements 106, including over the conductive interconnect layer 108.

As shown in FIG. 3B, a layer of photoimageable epoxy 112 is then formed on the upper surface of the passivation layer 110 utilizing techniques well known to those skilled in the art, e.g., utilizing spin-on techniques. The thickness of the epoxy layer 112 may be about 250 Photolithographic techniques well known to this skilled in the art are then utilized to mask and etch the epoxy layer 112 and the passivation layer 110 to form at least one via opening that extends from the upper surface of the epoxy layer 112 to the conductive interconnect layer 108. A conductive via 116 is formed in the via opening(s) by, for example, electroplating techniques well known to those skilled in the art.

As shown in FIG. 3C, a conductive inductor coil 114 is then formed on the upper surface of the epoxy layer 112 in contact with the conductive vias 116.

As shown in FIG. 3D, a back side trench may be etched into the back side 104b of the semiconductor substrate 104 utilizing etch techniques well know to those skilled in the art.

It should be understood that the particular embodiments of the invention described above have been provided by way of example and that other modifications may occur to those skilled in the art without departing from the scope of the invention as expressed in the appended claims and their equivalents.

What is claimed is:

1. An on-chip inductor structure formed as part of an integrated circuit structure, the integrated circuit structure including a semiconductor substrate having a top side and a back side, circuit elements formed on the top side of the substrate, a conductive interconnect layer formed in contact with the circuit elements and a passivation layer formed over the integrated circuit elements, the inductor structure comprising:
a layer of photoimageable epoxy formed on the passivation layer;
a conductive inductor coil formed on the layer of photoimageable epoxy; and
at least one conductive via that extends from the conductive inductor coil to the interconnect layer to provide electrical contact therebetween.

2. The on-chip inductor structure of claim 1, wherein the semiconductor substrate includes a back side trench formed in the back side of the semiconductor substrate beneath the inductor coil.

3. The on-chip inductor structure of claim 1, wherein the passivation layer is about 600 nm-1 μm thick.

4. The on-chip inductor structure of claim 1, wherein the photoimageable epoxy layer is about 250 μm thick.

5. The on-chip inductor structure of claim 1, wherein the conductive inductor coil comprises a spiral coil.

6. The on-chip inductor structure of claim 5, wherein the spiral inductor coil comprises copper.

7. A method of forming an on-chip inductor structure as part of an integrated circuit structure, the integrated circuit structure including a semiconductor substrate having a top side and a back side, circuit elements formed on the top side of the substrate, a conductive interconnect layer formed in contact with the integrated circuit elements, and a passivation layer formed over the circuit elements, the method comprising:
forming a layer of photoimageable epoxy on the passivation layer;
forming at least one conductive via contact that extends from an upper surface of the layer of photoimageable epoxy to the conductive interconnect layer; and
forming an inductor coil on the upper surface of the layer of photoimageable epoxy in contact with the at least one conductive via contact.

8. The method of claim 7, and further comprising:
forming a back side trench in the back side of the semiconductor substrate beneath the inductor coil.

9. The method of claim 7, wherein the passivation layer is about 600 nm-1 μm thick.

10. The method of claim 7, wherein the photoimageable epoxy layer is about 250 μm thick.

11. The method of claim 7, wherein the at least one conductive via contact is formed utilizing electroplating.

12. The method of claim 7, wherein the conductive inductor coil is formed utilizing electroplating.

13. The method of claim 7, wherein the conductive inductor coil comprises a spiral coil.

14. The method of claim 7, wherein the conductive inductor coil comprises copper.

15. The method of claim 7, wherein, the conductive interconnect layer comprises a material selected from the group consisting of Al, Cu and alloys thereof.
